(19) United States
(12) Patent Application Publication
(10) Pub. No.: US 2024/0098846 A1
(43) Pub. Date: Mar. 21, 2024

(54) Control Device and Method of Manufacturing a Control Device

(71) Applicant: Eberspächer catem GmbH & Co. KG, Herxheim (DE)

(72) Inventors: Simon Georg Kräck, Karlsruhe (DE); Timo Kröner, Rülzheim (DE)

(21) Appl. No.: 18/368,319

(22) Filed: Sep. 14, 2023

(30) Foreign Application Priority Data
Sep. 15, 2022 (DE) 10 2022 123 568.8

(51) Int. Cl. H05B 1/02; F24H 3/04; H05K 5/00

(52) U.S. Cl. CPC H05B 1/0202; F24H 3/0441; H05K 5/0069; H05B 2203/02; H05B 2203/023

(57) ABSTRACT

A control device for an electric heating device has a control housing which surrounds a printed circuit board and which accommodates a power switch. The power switch makes contact with the printed circuit board via a contact pin. An alignment element is penetrated by the contact pin is attached to the printed circuit board, and is formed with at least one passage for the contact pin. The passage is aligned with a plug-in slot of the printed circuit board and has a widened opening on its side opposite the printed circuit board. The widened opening tapers in the direction of the passage via a ramp surface. In the manufacturing method, the power switch is approached to the plug-in slot of the printed circuit board and the alignment element. As part of this approach, the contact pin is aligned with the plug-in slot by sliding on the ramp surface.

### BACKGROUND OF THE INVENTION

### 1. Field of the Invention

The present invention relates to a control device, in particular for an electric heating device with a PTC element as an auxiliary heater in a motor vehicle.

### 2. Background of Related Art

Control devices, in particular for electric heating devices with a ceramic PTC element for heating motor vehicles, are sufficiently described in the prior art, for example in EP 1 872 986 A1 or EP 2 337 425 A1. A control device in such an electric heating device usually has a control housing which surrounds the control components and is provided with plug-in connections for connecting control signals and/or the power current to be controlled. The previously described examples as well as the electric heating device from EP 3 334 242 A1 realize a concept in which the control device is provided integrally with the power section. The control device has at least one power switch, which emits power loss during operation. This is usually supplied to the medium to be heated. Accordingly, the power switch is not only provided with a cooling element which dissipates the power loss and accordingly counteracts overheating of the power switch. The cooling element is rather thermally coupled with the fluid to be heated. For this purpose, the cooling element can be provided in a heating chamber, which is separated from the accommodation chamber of the control housing by a partition wall, in which the part of the cooling element in contact with the power switch is accommodated. Usually, a partition wall is provided between the accommodation chamber of the control housing and the heating chamber, which delimits both the heating chamber and the accommodation chamber of the control housing. In this context, this control housing can also accommodate contact zones of PTC heating assemblies, which usually protrude into the heating chamber and comprise at least one PTC element. Thus, in the prior art, the interior of the control housing is also referred to as connection chamber, since the contact zones in this chamber are electrically connected.

The previously mentioned features also apply to the realization of the control device according to the invention in an electric heating device with a ceramic PTC element as auxiliary heater.

EP 2 330 865 A1 and EP 1 630 013 A1 respectively disclose examples of control devices for an electric heating device for a motor vehicle. In these previously known heating devices, power switches are electrically contacted with the printed circuit board and also heat-conductively connected with a cooling element. The corresponding arrangement is made in the course of assembling the printed circuit board, insofar as it is already equipped with the power switches. Regardless of the actual procedure in the course of assembly, attention must be paid to the fact that, on the one hand, the power switches are accommodated with their contact pins in the corresponding plug-in slots of the printed circuit board, which requires exact positioning of the power switch relative to the printed circuit board, and, on the other hand, the power switches are positioned relative to the cooling surface. The power switches are usually connected under pretension so that good thermal coupling is ensured. Regularly, there is an electrical insulation between the cooling surface and the power switch, which prevents the power switch from being in direct electrical contact with the cooling surface. Such a configuration is particularly necessary for electrical systems such as heating devices in a motor vehicle if they are operated with a high-voltage power current. This is particularly the case with electric heating devices for electromobility that are operated at a voltage of 48 volts or more. Here, particular attention must be paid to electrical safety.

### SUMMARY

The present invention aims to provide a control device that can be easily and inexpensively manufactured.

In accordance with an aspect of the invention, an electric heating device is provided that comprises a printed circuit board, a control housing which surrounds the printed circuit board and which accommodates a power switch that makes contact with the printed circuit board via a contact pin, and an alignment element. The alignment element is penetrated by the contact pin, is attached to the printed circuit board, and which is formed with at least one passage for the contact pin. The alignment is aligned with a plug-in slot of the printed circuit board and has a widened opening on a side thereof that is opposite the printed circuit board. The widened opening tapers in the direction of the passage via a ramp surface. The control housing may be provided as a structural unit with the housing of a power section in which the power current controlled by the control device is used to operate electrical components. The control housing may also be implemented separately. The control housing usually has a cooling element for heat-conducting contact of the power transistor. This cooling element may be formed by or in a partition wall that typically surrounds a connection chamber formed in the control housing. The connection chamber may be a chamber within the control housing in which also the PTC heating assemblies of the electric heating device are connected. However, the understanding of the connection chamber feature is not limited to this. This is because an electrical connection is also made, for example, for the electrical or electronic components, in particular the power switch, which is connected to the printed circuit board.

For heat-conducting contacting of the power switch, the printed circuit board can have a recess through which the power switch contacts the cooling surface. However, the power switch can also be contacted with the printed circuit board such that the body of the power switch is provided next to the printed circuit board and abuts against a cooling element there.

A power switch according to the present invention can, for example, be formed by a MOSFET or an IGBT. The abutment against the cooling surface can be made by interposing an electrically insulating film, for example a polyimide film, in order to electrically decouple the cooling surface from the power switch, but nevertheless allow good heat conduction from the power switch to the cooling surface.

This alignment element is attached to the printed circuit board. An attachment in this sense is already provided by the fact that the alignment element is fixed in a direction transverse to the extension of the printed circuit board. Such an attachment can, for example, be made by a bore within the printed circuit board and/or be a form-fitted enclosure, for example in the form of a clip connection, in which the alignment element engages behind the printed circuit board at the edge or within a recess provided in the printed circuit board.

By attaching the alignment element relative to the printed circuit board in such a manner, the alignment element enables precise insertion of the contact pin in the course of assembly. Namely, the alignment element according to the present invention has a passage for the contact pin with a funnel-shaped configuration extending from the insertion side, i.e. the side of the alignment element opposite the printed circuit board. For this purpose, the alignment element has an opening which is widened with respect to the passage. This opening tapers in the direction of the passage via a ramp surface. In this case, the ramp surface should taper in the manner of a funnel from all edges of the opening centrally towards the passage. The ramp surface may be inclined at an angle of between 30° and 60° relative to the central longitudinal axis of the diffuser. The funnel opening merges into the free surface of the alignment element over a soft radius (for example R=0.1 mm) The opening should be dimensioned such that, in the event of conceivable tolerance deviations between the plug-in slot and the position of the contact-side section of the contact pin to be inserted into the printed circuit board, the same is always inserted at least into the opening. With progressive approach of the power transistor to the printed circuit board, the free end of the contact pin slides along the ramp surface and is thereby forced towards the passage and thus the plug-in slot. The plug-in slot and the passage are aligned with each other such that the contact pin must penetrate the alignment element with its front end aligned exactly with the plug-in slot. In other words, the alignment element according to the invention causes the free end of the contact pin to be aligned at right angles to the extension direction of the printed circuit board.

The solution according to the invention offers the advantage that, during manufacture of the control device in the context of contacting the power switch, its contact pin only has to be roughly aligned relative to the plug-in slot. Any positional deviations are compensated for by the ramp surface. Due to their bendability, the individual contact pins can thereby follow the guided alignment by the alignment element without the need to change the position of the power transistor. At the end of the insertion movement, the contact pin is located with its contact-side section or end inside the plug-in slot. There, the contact pin can be bonded, for example by soldering. ThE contact pin may be contacted with at least one strip conductor of the printed circuit board via a connection element which comprises spring-biased female contact segments which, when the contact pin is inserted into the plug-in slot in the manner of a female plug-in contact, inevitably make electrical contact with the contact pin. Such an electrical connection element is described, for example, in EP 2 236 330 A1 and a U.S. counterpart thereof, U.S. Pat. No. 8,803,036, both of which are of the present applicant and both of which are incorporated by reference. Thus, in one, direct plug-in contacting takes place when the contact pin is inserted by the alignment element into the plug-in slot. The corresponding connecting piece may be attached to the printed circuit board as described in the aforementioned prior art and, in any case, is accommodated with its elastic contact tongues within a bore of the printed circuit board. Additional protection of the printed circuit board can be provided by supporting the alignment element relative to the printed circuit board with interposition of this connection element. The connection element usually abuts flatly on the printed circuit board. The alignment element also may abut the printed circuit board with selected, rather small-area areas. In this way, the local support force of the alignment element, which can lead to increased mechanical stress on the printed circuit board, in particular when the contact pin is inserted, can be distributed flatly over the printed circuit board via the connecting piece.

The alignment element has several passages. The number of passages usually corresponds to the number of contact pins of a single power switch. This is because the individual contact pins of a power switch are positioned and spaced apart relative to each other by the configuration of the power switch. This predetermined allocation of the contact pins corresponds to the arrangement of the passages and the corresponding ramp surfaces to them on the alignment element.

Usually, a control device is provided with several power switches. For this case, according to a possible further development of the present invention, it is proposed that one alignment element of the present invention is provided for each of the power switches.

The alignment element is usually a component made of plastic by injection molding. It can form a plurality of contact surfaces that are supported on the aforementioned connecting piece and/or on the upper side of the printed circuit board. The alignment element can also be supported on the printed circuit board by these contact surfaces alone and project above the corresponding connecting piece in a contact-free manner With regard to solid support of any reaction forces when inserting the contact pin into the alignment element, the alignment element can be supported on the side of the printed circuit board opposite the power switch with respect to the connection housing. This significantly reduces the mechanical stress on the printed circuit board when the contact pin is inserted. The alignment element can have several corresponding supports relative to the control housing. These supports can be formed by pins which penetrate bores of the printed circuit board and/or by further elements which engage behind or over the printed circuit board at the edge and are supported relative to the control housing.

In a manner generally known, the control device may have a partition wall provided with a cooling element. The power switch is applied in a heat-conducting manner against a cooling surface formed by the cooling element. A hold-down device is provided in the control housing, which is provided on the side of the power switch opposite the cooling surface and acts from there against the power switch, usually with the interposition of an elastic element, such as a spring device. In any case, by means of the hold-down device, the power switch is reliably applied against the cooling surface. The further development now proposes to provide the power switch and the hold-down device in a pre-assembled module. This module can accommodate several power switches. The module is handled uniformly as part of the assembly. In particular, such a configuration may result in certain misalignments of at least individual contact pins of the power switch(es) such that these contact pins are not exactly aligned with the corresponding plug-in slot within the printed circuit board. Thus, the present invention proves particularly advantageous when inserting the power switch(es) as part of a pre-assembled module.

According to its parallel aspect, the present invention proposes an electric heating device having a control device as described above, a heater housing which forms a heating chamber separated from the control device by a partition wall, and at least one PTC heating assembly that protrudes from the partition wall as a heating fin into the heater housing. The PTC heating assembly comprises at least one PTC element, and conductor elements which are electrically conductively connected to the PTC element and which are electrically connected in the control housing, the conductor elements being configured to energize the PTC element with a different polarity

This electric heating device has, in the manner already known from EP 2 466 989 A1, a partition wall between a control housing and a heater housing. This partition wall usually forms, in the manner already known from EP 2 466 989 and U.S. counterpart 20120087642 (both incorporated by reference), both a closure of a heating chamber formed by the heater housing and a closure of the control housing. The PTC heating assembly can be accommodated in the partition wall with plug-in contacts or otherwise sealed and/or fixed in position relative thereto. The strip conductors can protrude into the control housing and can be plug-in contacted with the printed circuit board, which also carries the power switch, or another printed circuit board, which is provided for grouping heating circuits comprising several PTC heating assemblies. A heat sink is exposed in the heating chamber and is heat-conductively connected to a cooling surface provided in the connection chamber. The power switch is applied against this cooling surface, so that the power dissipated by the power switch can also be used to heat the fluid to be heated in the heating device. This fluid can be a liquid fluid or a gaseous fluid, in particular air. The hold-down device mentioned above is provided in the control housing, which joins the power switch(es) into one module. The hold-down device can be connected, in particular clipped, to a positioning frame which forms an accommodation for each power switch.

Also disclosed is a method of manufacturing a control device, comprising causing a contact pin of a power switch to approach a plug-in slot of a printed circuit board and an alignment element arranged on the printed circuit board, which alignment element has a passage that is aligned with the plug-in slot, and which has, on a side opposite the printed circuit board, a widened opening which tapers in a direction of the passage via a ramp surface. The method further includes, as part of the approach, aligning the contact pin with the plug-in slot by sliding the contact pin on the ramp surface.

The may further comprising, after approaching, moving the contact pin through the passage, though an opening of the passage that faces the plug-in slot, and then moving the contact pin into the plug-in slot.

### BRIEF DESCRIPTION OF THE DRAWINGS

Further details and advantages of the present invention will be apparent from the following description in conjunction with the drawing. Therein:

FIG. 1 shows a perspective exploded view of an embodiment of an electric heating device;

FIG. 2 shows a longitudinal sectional view of a PTC heating assembly of the heating device according to FIG. 1;

FIG. 3 shows a perspective side view of a module above the printed circuit board and the cooling element;

FIG. 4 shows a longitudinal sectional view of a module after assembly;

FIG. 5 shows a cross-sectional view of the module according to FIG. 3;

FIG. 6 shows a perspective side view of an alignment element before assembly;

FIG. 7 shows a perspective side view of an alignment element after assembly;

FIG. 8 shows an enlarged detail of FIG. 5;

FIG. 9 shows a top view of the illustration according to FIG. 8.

### DETAILED DESCRIPTION

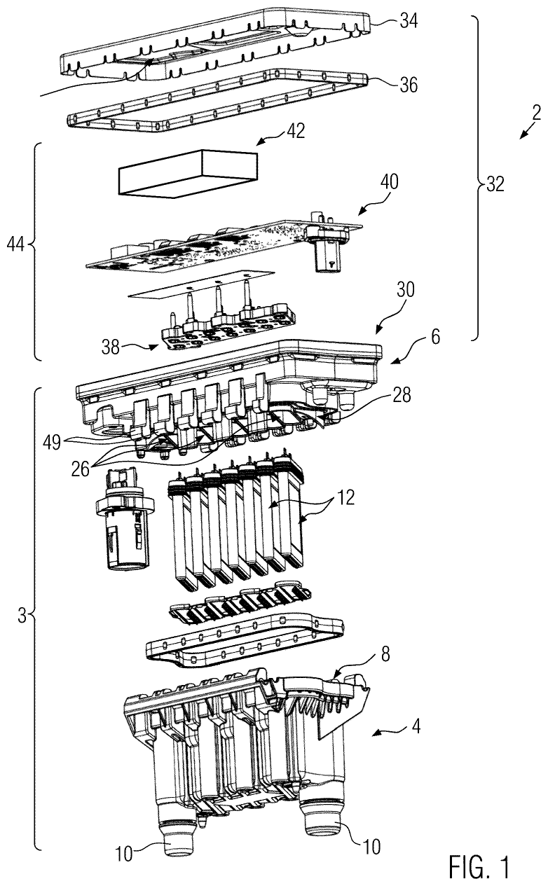

FIG. 1 shows an embodiment of an electric heating device 2 with a multi-part heater housing 3 comprising a housing lower part 4 formed of plastic and a housing upper part 6 integrally formed of metal by means of die casting.

The housing lower part 4 is trough-shaped, encloses a heating chamber 8 and forms openings to inlet and outlet ports 10 which communicate with the heating chamber 8. These inlet and outlet ports 10 are integrally formed with the housing lower part 4 by injection molding. A plurality of PTC heating assemblies 12 are shown between the housing upper part 6 and the housing lower part 4.

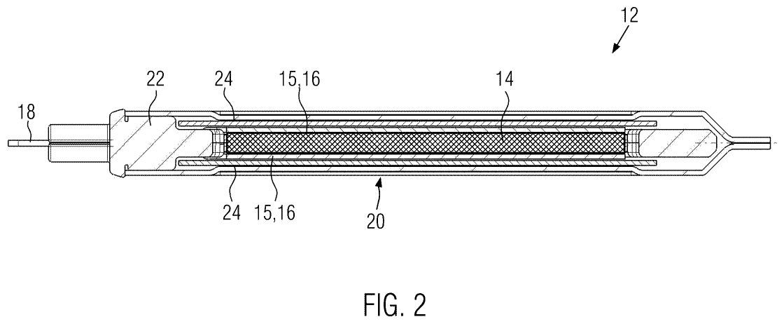

As illustrated in FIG. 2, these PTC heating assemblies 12 each have at least one PTC element 14 against which conductor elements 15 in form of contact sheets 16 abut, which form contact tongues 18 that extend beyond a metal housing 20. The PTC element 14 is accommodated in a frame 22 and between the contact sheets 16. Between each of the metallic housing 20 and the contact sheets 16 an insulating layer 24 is provided.

The PTC heating assemblies 12 are held in plug-in contact in accommodations 26 provided for this purpose in a partition wall 28 of the housing upper part 6. Details of this configuration are described in EP 3 334 242 A1, which originates from the applicant.

On the side of the partition wall 28 opposite the PTC heating assemblies 12, a connection chamber 30 is formed, which is surrounded by a control housing 32 comprising a control housing cover 34, which is connected to the housing upper part 6 in a sealed manner via a seal 36. A first printed circuit board 38 is located in the connection chamber 30, which accommodates the contact tongues 18 and groups the individual PTC heating assemblies 12 into heating circuits.

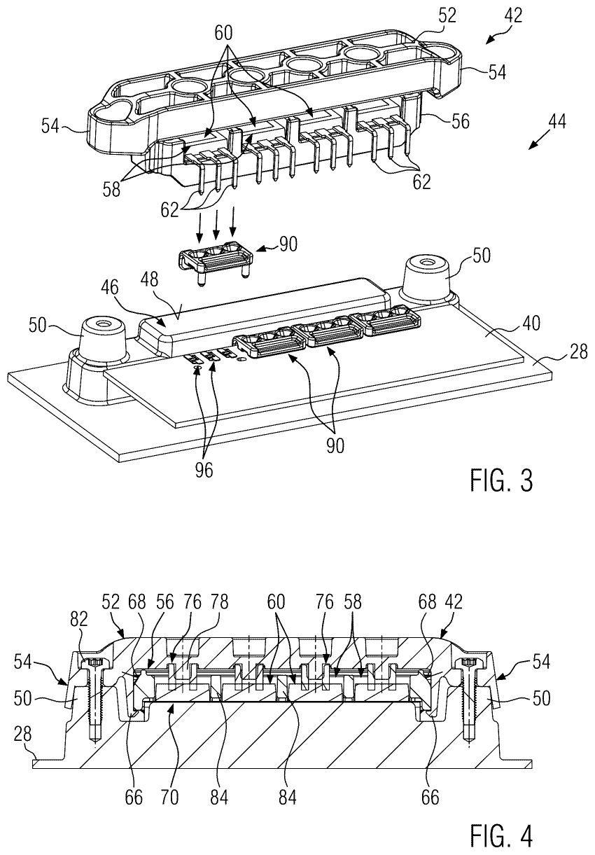

In the control housing 32, a second printed circuit board characterized by reference sign 40 is provided, which is equipped with electronic components not shown in detail. Reference sign 42 characterizes a module shown in more detail in further FIG. 3 et seq. which is part of the control device characterized by reference sign 44 in FIG. 1.

Next to the module 42, FIG. 3 schematically shows the partition wall 28 from which a cooling element 46 projects in the direction of the connection chamber 30. This cooling element 46 forms a flat cooling surface 48. The cooling elements 46 are extended into the heating chamber 8 and form heat sinks 49 there. In extension of the cooling surface 48 and adjacent thereto, the housing upper part 6 also forms form-fit segments 50 on the side of the cooling element, which also protrude as slightly conical projections from the partition wall 28 presently schematically shown flatly.

The module 42 includes a hold-down device 52 that is formed as an elongated plastic component and forms form-fit mating segments 54 at its respective ends, which can positively cooperate with the form-fit segments 50 to position the hold-down device 52 relative to the housing upper part 6 and thus the control housing 32.

With reference sign 56, a positioning frame is characterized that forms a plurality of accommodations 58 for power switches 60. Each power switch 60 has three contact pins, characterized by reference sign 62, that are bent about 90 degrees approximately centrally and have a contact-side section 64 that extends substantially perpendicular to the major extension of the printed circuit board 40.

As FIG. 4 conveys, the hold-down device 52 has lateral detents 66 that encompass the positioning frame 56 on the underside. The side of the module 42 facing the printed circuit board 40 is referred to as the underside. Corresponding to these detents 66, the positioning frame 56 has ramp surfaces 68 on its upper side against which the detents 66 slide in the course of assembly when the hold-down device 52 is clipped to the positioning frame 56.

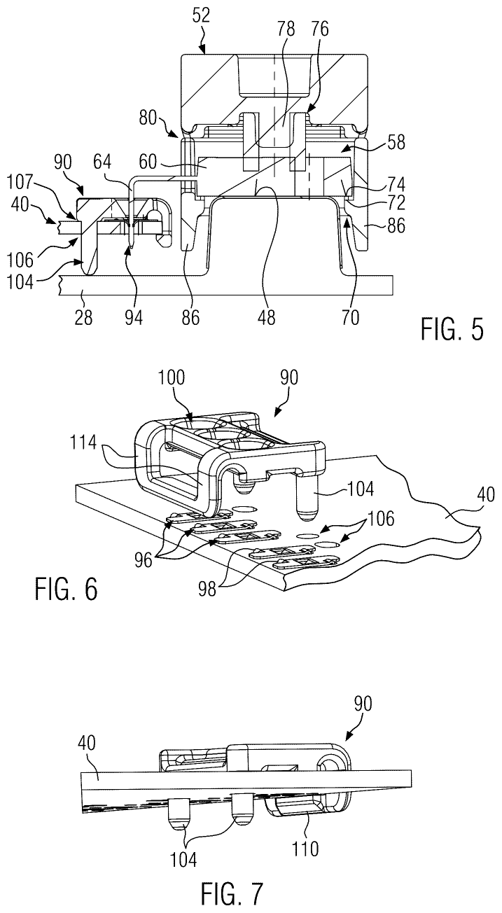

As can be seen from FIGS. 4 and 5, the accommodations 58 are substantially adapted to the dimensions of the power switches 60. On the underside, the positioning frame 56 forms an opening 70 in which the power switches 60 are each exposed. The opening 70 is bounded by a web 72 projecting toward the opening 70, which forms a support 74 for the power switch 60. FIGS. 4 and 5 furthermore show a spring device configured as a silicone spring 76 in the form of a hollow body. The silicone spring 76 is configured as a short piece of tubing and is pushed onto a pin 78 formed by the hold-down device 52, resulting in a form-fit connection between the silicone spring 76 and the hold-down device 52, by means of which the silicone spring 76 is fixed at right angles to its spring force relative to the hold-down device 52.

In the course of assembly, the individual components are first provided. Then the silicone spring 76 can be pushed onto the respective pins 78 in order to provide the hold-down device 52 with the spring devices. In parallel, the individual power switches 60 are inserted into the accommodations 58 assigned to them. For this purpose, the positioning frame 56 has a window, characterized by reference sign 80 in FIG. 5, which allows the power switch 60 to be lowered into the accommodation 58 without impairing the alignment of the contact pins 62. After the respective power switches 60 have been assembled, they rest on the support 74. The hold-down device 52 is then approached to the positioning frame 56. In the process, the detents 66 slide past the ramp surfaces 68. The detents 66 are spread and spring back on the underside of the positioning frame 56, forming a form-fit connection between the hold-down device 52 and the positioning frame 56. As part of this joining motion, the silicone springs 76 are accommodated between the hold-down device 52 and the power switches 60, slightly pretensioned if necessary. The module 42 thus produced is then assembled in the control housing 32. For this purpose, the module 42 is approached to the housing upper part 6. In the process, the cooling element 46 penetrates the opening 70 and is applied against the power switches 60 in a heat-conducting manner. An insulating layer, for example in the form of a polyimide film or a ceramic layer, is usually inserted beforehand between the cooling surface 48 and the power switches 60 to prevent direct electrical contact between the power switch 60 and the cooling element 46. The joining motion may be guided by the interaction of the form-fit segments 50 with the form-fit mating segments 54. This may result in pre-positioning of the module 42 relative to the cooling element 46.

Subsequently, screws characterized by reference sign 82 are screwed into the housing upper part 6. These have the effect of fixing the hold-down device 52 to the housing upper part 6 and thus compressing the silicone springs 76 and accordingly applying the power switches 60 under pretension. Obviously, the opening is appropriately dimensioned so that the cooling element 46 can easily immerse into the positioning frame 56. Cross beams 84 of the positioning frame 56, which bound the individual accommodations 58 in the longitudinal direction of the hold-down device 52 and separate the respective accommodations 58 from one another, allow a corresponding movement. These cross beams 84 are reduced in height compared to the longitudinal beams 86 drawn in FIG. 5.

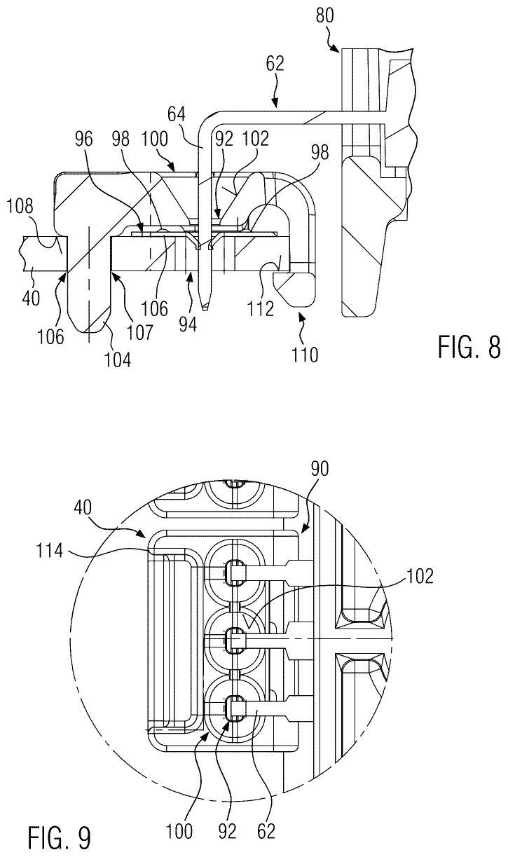

FIGS. 6 to 9 illustrate an alignment element of a plastic material characterized by reference sign 90 in FIG. 5. This serves to facilitate insertion of the contact-side section 64 of the contact pin into the printed circuit board 40. The alignment element 90 has a passage 92 which is aligned with a plug-in slot 94 for the respective contact pin 62 within the printed circuit board 40. The plug-in slot 94 is created by a connecting piece 96 which is electrically contacted with at least one strip conductor of the printed circuit board 40, the details of which are described in EP 2 236 330 A1 and which is shown in FIGS. 6 and 8. This connecting piece 96 lies basically flatly on the upper side of the printed circuit board 40. Only upwardly curved radii 98 of retaining webs which engage in bores of the printed circuit board 40 project slightly beyond the otherwise flat surface of the connecting pieces 96.

As can be seen in particular from FIGS. 8 and 9, the alignment element 90 has a significantly widened opening 100 around the passage 92 on the side facing away from the printed circuit board 40 compared to the dimensions of the passage 92. This opening 100 merges into the passage 92 without a shoulder via inwardly inclined ramp surfaces 102. The alignment element 90 is mounted on the printed circuit board 40 such that the passage 92 is precisely aligned with the plug-in slot 94 within the printed circuit board 40. For this purpose, the alignment element 90 comprises positioning pins 104 that extend through a positioning bore 106 within the printed circuit board 40 and project beyond the printed circuit board 40 on the underside. The positioning pins 104 extend from a protrusion that forms a contact surface 108, which is provided annularly around the positioning pin 104. The alignment element 90 is applied against the printed circuit board 40 via the contact surfaces 108. As can be seen from FIGS. 6 and 7, two positioning pins 104 and corresponding positioning bores are provided for each alignment element 90. Through this interaction, elements of a form-fit connection 107 are already provided by which the alignment element 90 is held transversely to the printed circuit board 40 in a form-fit manner and is fastened in this sense.

As can be seen in particular from FIGS. 6, 7, and 8, the alignment element 90 further has a latching leg 110 that forms a latching surface 112 abutting against the underside of the printed circuit board 40. This latching leg 110 also clips against the printed circuit board 40. The latching leg 110 is tethered by two connecting webs 114 that abut against the front surface of the printed circuit board 40 with a certain transverse spacing. By this configuration, the printed circuit board is encompassed at the edge by the alignment element 90.

As FIG. 5 illustrates, the free ends of the positioning pins 104 abut against the partition wall 28. In this way, the alignment element 90 is supported locally in the area of the passage 92, which mechanically relieves the printed circuit board 40 when the contact pins 62 are inserted.

As can be seen from FIG. 6, the alignment element 90 shown there has a plurality of passages 92 with corresponding openings 100 and ramp surfaces 102. The comparison of this illustration with FIG. 3 conveys that a single alignment element 90 is provided for each power switch 60. Thus, the number of passages 92 per alignment element 90 corresponds to the number of contact pins 62 of the power switch 60. FIG. 3 conveys four alignment elements 90 connected in series side by side with the printed circuit board 40.

In the course of assembling the module 42, the individual contact pins 62 with their contact-side sections 64 are aligned with the plug-in slots 94 via the respective ramp surfaces 102 of the corresponding alignment elements 90. Any misalignment is usually compensated for by the elasticity of the contact pins 62.

1. A control device for an electric heating device, comprising:
a printed circuit board;
a control housing which surrounds the printed circuit board and which accommodates a power switch that makes contact with the printed circuit board via a contact pin;
an alignment element which is penetrated by the contact pin, which is attached to the printed circuit board), and which is formed with at least one passage for the contact pin, wherein the alignment element is aligned with a plug-in slot of the printed circuit board and has a widened opening on a side thereof that is opposite the printed circuit board, wherein the widened opening tapers in the direction of the passage via a ramp surface.

2. The control device according to claim 1, wherein the alignment element is positively held to the printed circuit board via a form-fit connection acting at least transversely to the printed circuit board.

3. The control device according to claim 2, wherein the alignment element positively engages a bore formed on the printed circuit board.

4. The control device according to claim 1, wherein the alignment element engages around an edge of the printed circuit board and is clipped relative to the printed circuit board.

5. The control device according to claim 1, wherein the alignment element has a plurality of passages located therein.

6. The control device according to claim 1, wherein a separate alignment element is provided for each power switch.

7. The control device according to claim 1, wherein the alignment element comprises an injection-molded component made of plastic.

8. The control device according to claim 1, wherein the alignment element is supported with respect to the printed circuit board with the interposition of a connecting piece which is electrically conductively connected to the contact pin and to a strip conductor of the printed circuit board.

9. The control device according to claim 2, wherein the alignment element projects beyond the printed circuit board on a side thereof opposite the power switch and is supported on the side of the printed circuit board relative to the control housing.

10. The control device according to claim 1, wherein the control housing comprises a partition wall which is provided with a cooling element and a hold-down device abutting the power switch in a heat-conducting manner against a cooling surface of the cooling element, and wherein the power switch and the hold-down device are provided in a pre-assembled module.

11. An electric heating device comprising:
a control device that includes
a printed circuit board, and
a control housing which surrounds the printed circuit board and which accommodates a power switch that makes contact with the printed circuit board via a contact pin,
an alignment element which is penetrated by the contact pin, which is attached to the printed circuit board, and which is formed with at least one passage for the contact pin, wherein the alignment element is aligned with a plug-in slot of the printed circuit board and has a widened opening on a side thereof that is opposite the printed circuit board, wherein the opening tapers in the direction of the passage via a ramp surface;
a heater housing which forms a heating chamber separated from the control device by a partition wall, and
at least one PTC heating assembly that protrudes from the partition wall as a heating fin into the heater housing, wherein the PTC heating assembly comprises at least one PTC element and conductor elements which are electrically conductively connected to the PTC element and which are electrically connected in the control housing, the conductor elements being configured to energize the PTC element with a different polarity.

12. A method of manufacturing a control device, comprising:
causing a contact pin of a power switch to approach a plug-in slot of a printed circuit board and an alignment element arranged on the printed circuit board, which alignment element has a passage that is aligned with the plug-in slot, and which has, on a side opposite the printed circuit board, a widened opening which tapers in a direction of the passage via a ramp surface; and
as part of the approach, aligning the contact pin with the plug-in slot by sliding the contact pin on the ramp surface.

13. The method according to claim 12, further comprising, after approaching, moving the contact pin through the passage, though an opening of the passage that faces the plug-in slot, and then moving the contact pin into the plug-in slot.
